(19) United States
(12) Patent Application Publication
(10) Pub. No.: US 2026/0301817 A1
(43) Pub. Date: Oct. 1, 2026

(54) OPERATION METHOD FOR MEMORY DEVICE AND MEMORY DEVICE

(71) Applicant: MACRONIX International Co., Ltd., Hsinchu (TW)

(72) Inventor: Ya-Jui Lee, Taichung City (TW)

(73) Assignee: MACRONIX International Co., Ltd., Hsinchu (TW)

(21) Appl. No.: 19/095,050

(22) Filed: Mar. 31, 2025

(51) Int. Cl. G11C 16/10; G11C 16/08; G11C 16/34

(52) U.S. Cl. CPC G11C 16/102; G11C 16/08; G11C 16/3459

(57) ABSTRACT

Disclosed are a memory device and an operation method for the same. The memory device may be a 3D NAND flash memory with high capacity and high performance. The operation method includes: dividing each of multiple dummy word lines into one of multiple dummy groups; performing a dummy word line programming operation on the multiple dummy word lines. The dummy word line programming operation includes: performing a first dummy word line programming operation on at least one first dummy word line divided into a first dummy group in the multiple dummy groups; performing a second dummy word line programming operation on at least one second dummy word line divided into a second dummy group in the multiple dummy groups. A programming bias of a first pulse in the first dummy word line programming operation is less than a programming bias of a second pulse in the second dummy word line programming operation. Time points for providing the first pulse and the second pulse to the plurality of dummy word lines respectively are different from each other.

### BACKGROUND

### Technical Field

The present disclosure relates to a data processing technology for a memory device (e. g., a three-dimensional (3D) NAND flash memory), and particularly relates to an operation method for a memory device and a memory device.

### Description of Related Art

High-capacity and high-performance integrated circuit memories including three-dimensional NAND flash memory (3D NAND flash memory) are under continuous development. The aim is to increase data storage density by utilizing three-dimensional stacking technology and triple-level cells (TLC) to reduce the size of memory cells.

In the process of manufacturing memory devices or memory arrays, dummy layers may be used as buffer zones for stacking memory decks, ensuring circuit structure configuration, reducing noise or interference, etc. The dummy memory cells in the dummy layers still possess corresponding threshold voltages, therefore they might still cause programming disturbance to adjacent memory cells, and might affect the data retention of memory cells.

### SUMMARY

The present disclosure provides an operation method for a memory device and a memory device, which may reduce programming disturbance of various memory cells in the memory device, and enable various memory cells to possess better data retention.

An embodiment of the present disclosure provides an operation method for a memory device. The memory device includes a memory block, and the memory block includes at least one memory cell string, wherein the at least one memory cell string includes a string select transistor, a plurality of memory cells and a ground select transistor sequentially connected in series. The at least one memory cell string further includes a plurality of dummy memory cells between the string select transistor and the plurality of memory cells, the plurality of memory cells, and the plurality of memory cells and the ground select transistor, wherein the plurality of memory cells are respectively coupled to a plurality of word lines, and the plurality of dummy memory cells are respectively coupled to the plurality of dummy word lines. The operation method includes: dividing each of the plurality of dummy word lines into one of the plurality of dummy groups; and, performing a dummy word line programming operation on the plurality of dummy word lines. The dummy word line programming operation includes: performing a first dummy word line programming operation on at least one first dummy word line divided into a first dummy group among the plurality of dummy groups; and, performing a second dummy word line programming operation on at least one second dummy word line divided into a second dummy group among the plurality of dummy groups. The programming bias of a first pulse in the first dummy word line programming operation is less than the programming bias of a second pulse in the second dummy word line programming operation.

The memory device provided in this embodiment of the present disclosure includes a memory array and a memory controller. The memory array includes at least one memory cell string. The at least one memory cell string includes a string select transistor, the plurality of memory cells and a ground select transistor sequentially connected in series. The at least one memory cell string further includes a plurality of dummy memory cells between the string select transistor and the plurality of memory cells, the plurality of memory cells, and the plurality of memory cells and the ground select transistor, wherein the plurality of memory cells are respectively coupled to the plurality of word lines, and the plurality of dummy memory cells are respectively coupled to the plurality of dummy word lines. The memory controller is configured to control the memory array. The memory controller is used to: divide each of the plurality of dummy word lines into one of the plurality of dummy groups; and, perform a dummy word line programming operation on the plurality of dummy word lines. The dummy word line programming operation includes: performing a first dummy word line programming operation on at least one first dummy word line divided into a first dummy group among the plurality of dummy groups; and, performing a second dummy word line programming operation on at least one second dummy word line divided into a second dummy group among the plurality of dummy groups. The programming bias of a first pulse in the first dummy word line programming operation is less than the programming bias of a second pulse in the second dummy word line programming operation.

In view of the foregoing, the embodiments of the present disclosure may divide the plurality of dummy word lines into the plurality of dummy groups according to many situations (e.g., the positional relationship of this dummy word line in the plurality of memory cell strings, the positional relationship between this dummy word line and other dummy word lines, the plurality of threshold voltage states to be retained in the plurality of memory cells adjacent to the plurality of dummy word lines). When performing the dummy word line programming operation on the dummy word lines, pulse signals with different programming bias are provided for dummy word lines in different dummy groups, thereby reducing the programming disturbance that each memory cell might receive from adjacent dummy memory cells, thus allowing each memory cell to possess better data retention.

### BRIEF DESCRIPTION OF THE DRAWINGS

FIG. 1 is a schematic view of a memory block, a memory controller and a memory cell string in a three-dimensional (3D) NAND memory device according to an embodiment of the present disclosure.

FIG. 2 is a schematic view illustrating how dummy memory cells affect adjacent memory cells using channel pillar CLP1 as an example according to an embodiment of the present disclosure.

FIG. 3 is a schematic view illustrating the ideal threshold voltages in corresponding transistors or memory cells using the ground select lines, dummy word lines and word lines in the memory cell string as examples according to an embodiment of the present disclosure.

FIG. 4 is a flowchart of an operation method of a memory device according to an embodiment of the present disclosure.

FIG. 5 is a schematic view illustrating the erase operation, the first to third dummy word line programming operations, and the dummy word line verification operation corresponding to the first to the third dummy groups respectively according to the first embodiment of the present disclosure.

FIG. 6 is a schematic view of various dummy word lines in the memory cell string according to an embodiment of the present disclosure.

FIG. 7 is a schematic view illustrating the erase operation, the first to third dummy word line programming operations, and the dummy word line verification operation corresponding to the first to the third dummy groups respectively according to the second embodiment of the present disclosure.

FIG. 8 is a schematic view illustrating the erase operation, the first to third dummy word line programming operations, and the dummy word line verification operation corresponding to the first to the third dummy groups respectively according to the third embodiment of the present disclosure.

FIG. 9 is a schematic view illustrating the erase operation, the first to third dummy word line programming operations, and the dummy word line verification operation corresponding to the first to the third dummy groups respectively according to the fourth embodiment of the present disclosure.

### DESCRIPTION OF THE EMBODIMENTS

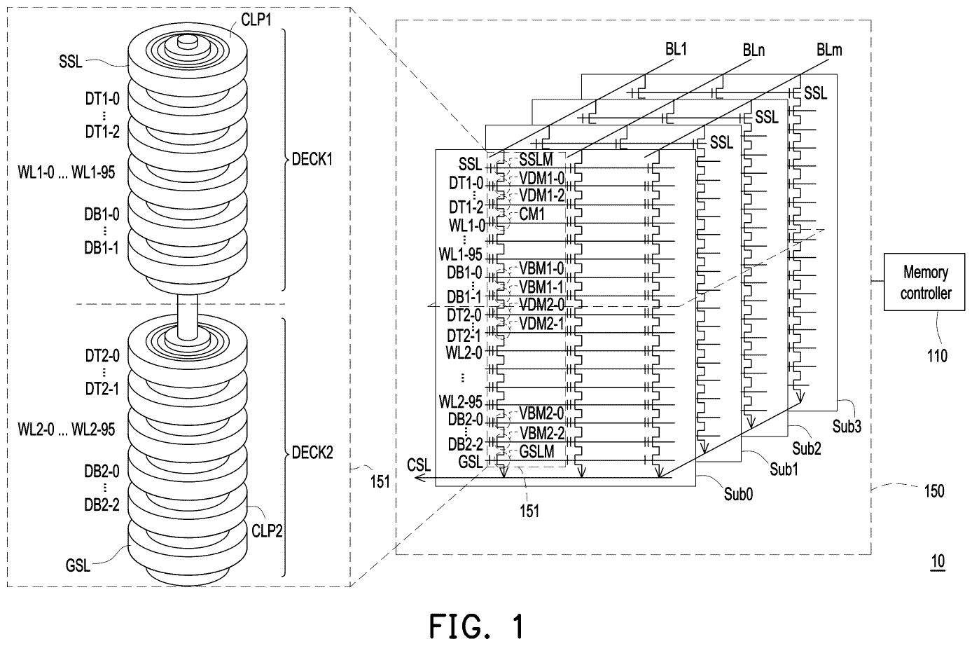

FIG. 1 is a schematic view of a memory block 150, a memory controller 110, and a memory cell string 151 in a three-dimensional (3D) NAND memory device 10 according to an embodiment of the present disclosure. The memory device 10 may be a 3D NAND flash memory. The memory block 150 may be part of a memory array in the memory device 10. Memory cells (e.g., memory cell CM1) are arranged in a three-dimensional manner in the memory block 150, for example, in an XYZ coordinate system. This does not mean that the circuitry of the 3D NAND memory device is limited to a three-dimensional manner. In an example, the memory block 150 may be divided into four sub-blocks (e.g., Sub0 to Sub3), each sub-block may be independently controlled and operated.

The memory cell string (e.g., memory cell string 151) includes a string select transistor (e.g., string select transistor SSLM), the plurality of memory cells (e.g., memory cell CM1), and a ground select transistor GSLM sequentially connected in series along the Z direction. A single memory cell (e.g., memory cell CM1) in the memory cell string 151 corresponds to a word line (e.g., word line WL1-0). A word line (e.g., word line WL1-0) may correspond to a layer in the XY plane.

The string select transistor SSLM is coupled to the string select line SSL (e.g., string select line SSL0), and the ground select transistor GSLM is coupled to the ground select line GSL. The string select transistor SSLM and the ground select transistor GSLM are located on opposite sides of the memory cell string 151. In this example, the plurality of memory cell strings coupled to the same string select line SSL on the same plane (e.g., a plane defined by the X direction and Z direction) may be defined as a sub-block (e.g., sub-block Sub0). Each memory cell string (e.g., memory cell string 151) is connected to a corresponding bit line (e.g., bit line BL1, BLn, or BLm) through the corresponding string select transistor SSLM on the string select line SSL. Memory cell strings in the same row in different sub-blocks (e.g., sub-block Sub0, Sub1 . . . etc.) along the Y direction are connected to corresponding bit lines.

The memory cell string (e.g., memory cell string 151) also includes dummy memory cells between the string select transistor SSLM and the plurality of memory cells (e.g., dummy memory cells VDM1-0 to VDM1-2), dummy memory cells between the plurality of memory cells (e.g., dummy memory cells VBM1-0 to VBM1-1, VDM2-0 to VDM2-1), and dummy memory cells between the plurality of memory cells and the ground select transistor GSLM (e.g., dummy memory cells VBM2-0 to VBM2-2). In other words, one or more dummy word lines (e.g., dummy word lines DT1-0 to DT1-2, DB2-0 to DB2-2) or dummy layers may be disposed between the string select line SSL and the word line layer (e.g., word line WL1-0), and between the ground select line GSL and the bottommost word line layer (e.g., word line WL2-95). Additionally, one or more dummy word lines (e.g., dummy word lines DB1-0 to DB1-1, DT2-0 to DT2-1) or dummy layers may be disposed in the middle portion of the memory cell string (e.g., memory cell string 151). The dummy memory cells VDM1-0 to VDM1-2, VBM1-0 to VBM1-1, VDM2-0 to VDM2-1, and VBM2-0 to VBM2-2 are coupled to the dummy word lines DT1-0 to DT1-2, DB1-0 to DB1-1, DT2-0 to DT2-1, and DB2-0 to DB2-2, respectively.

In this embodiment, the memory block (e.g., memory block 150 in FIG. 1) may be formed by overlapping one or more memory stack layers. The dummy memory cells and corresponding dummy word lines form the plurality of dummy layers, and these dummy layers are disposed at the boundary positions on both sides of the memory stack layers (e.g., memory stack layers DECK1 to DECK2). For example, the memory block 150 in FIG. 1 is formed by stacking two memory stack layers DECK1 to DECK2. Dummy layers formed by dummy word lines DT1-0 to DT1-2 and DB1-0 to DB1-1 and corresponding dummy memory cells VDM1-0 to VDM1-1 and VBM1-0 to VBM1-1 are disposed on both sides of the memory stack layer DECK1. Dummy layers formed by dummy word lines DT2-0 to DT2-1 and DB2-0 to DB2-2 and corresponding dummy memory cells VDM2-0 to VDM2-1 and VBM2-0 to VBM2-2 are disposed on both sides of the memory stack layer DECK2. Each of the memory cell strings includes one or more channel pillars, and these one or more channel pillars correspond to one or more memory stack layers respectively. For example, the memory cell string 151 includes two channel pillars CLP1 to CLP2, and the channel pillars CLP1 to CLP2 correspond to the memory stack layers DECK1 to DECK2, respectively. The dummy memory cells (e.g., dummy memory cells VDM1-0 to VDM1-1, VBM1-0 to VBM1-1, VDM2-0 to VDM2-1, and VBM2-0 to VBM2-2) are disposed at the boundary positions of the channel pillars CLP1 and CLP2.

The string select line SSL may be a conductive wire or conductive layer formed above the topmost dummy word line layer (e.g., dummy word line DT1-0). Each memory cell string (e.g., memory cell string 151) may be connected to the same common source line CSL through a corresponding ground select transistor on the ground select line GSL. The ground select line GSL may be a conductive wire or conductive layer formed below the bottommost dummy word line layer (e.g., dummy word line DB2-2). The common source line CSL may be a conductive layer formed above the substrate of the 3D memory device. The string select lines SSL in the memory block 150 may be on the same conductive layer, but divided into independent wires. Each independent wire (string select line SSL) may independently control the operation of corresponding sub-blocks (e.g., sub-blocks Sub0, Sub1, etc.) in the memory block 150.

In an example, the plurality of memory cells (including memory cell CM1) coupled to the same word line or word line layer (e.g., word line WL1-0) in a sub-block (e.g., sub-block Sub0) may be defined as one page (in Single-Level Cell (SLC) mode). In another example, the plurality of memory cells (including memory cell CM1) coupled to the same word line or word line layer (e.g., word line WL1-0) in a sub-block (e.g., sub-block Sub0) may be defined as three pages (in Triple-Level Cell (TLC) mode). In TLC mode, these three pages include a high page, a middle page, and a low page. The same voltage is applied to memory cells CM1 located on the same word line (e.g., word line WL1-0). Each word line (e.g., word line WLn) may be connected to a driving circuit, such as an X decoder (or scan driver). The memory device 10 also includes a memory controller 110 for implementing corresponding operations on the memory cells.

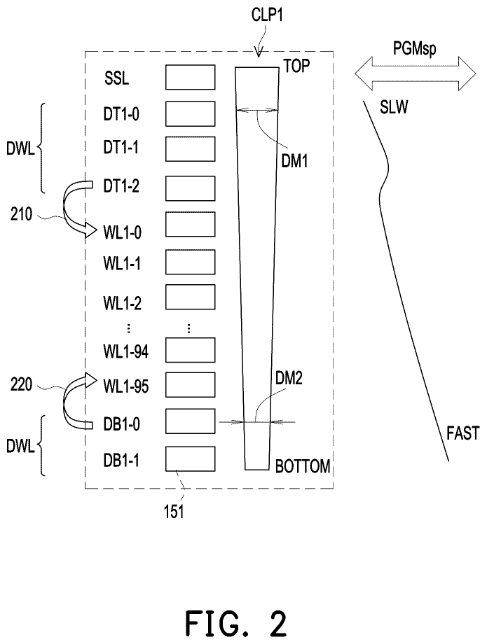

FIG. 2 is a schematic view illustrating how dummy memory cells affect adjacent memory cells using channel pillar CLP1 as an example according to an embodiment of the present disclosure. FIG. 2 shows the channel pillar CLP1 in the memory cell string 151 including a string select line SSL, dummy word lines (DWL) DT1-0 to DT1-2, word lines WL1-0 to WL1-95, and dummy word lines DB1-0 to DB1-1. In this embodiment, three layers and two layers of dummy layers are disposed at the boundary positions on both sides of the memory stack layer and the corresponding channel pillar CLP1, respectively. Those applying this embodiment may adjust the number of dummy layers on both sides of the memory stack layer according to their needs.

The dummy memory cells in the dummy layers still possess threshold voltages, and based on the charge diffusion effect, the dummy memory cells on the dummy word line DT1-2 (e.g., dummy memory cell VDM1-2 in FIG. 1) might still cause programming disturbance to the memory cells on the adjacent word line WL1-0, affecting the data retention of the memory cells (as indicated by arrow 210). Similarly, the dummy memory cells on the dummy word line DB1-0 (e.g., dummy memory cell VBM1-0 in FIG. 1) might cause programming disturbance to the memory cells on the adjacent word line WL1-95 (as indicated by arrow 220).

On the other hand, the channel pillar CLP1 might not be an ideal cylindrical shape. Different cross-sectional positions in the channel pillar CLP1 might have different diameters. Due to the varying diameters at different positions in the channel pillar CLP1, memory cells located at different positions in the channel pillar CLP1 require different programming bias levels during programming operations, resulting in different programming speeds PGMsp. For example, the channel pillar CLP1 is approximately conical, with the diameter at the top TOP of the channel pillar CLP1 being greater than the diameter at the bottom BOTTOM of the channel pillar CLP1, and the diameter DM1 corresponding to the dummy word line DT1-0 in the channel pillar CLP1 is greater than the diameter DM2 corresponding to the dummy word line DT1-0. Therefore, the dummy memory cells corresponding to the dummy word line DT1-0 in FIG. 2 have a slower programming speed PGMsp (e.g., marked as SLW in FIG. 2), while the dummy memory cells corresponding to the dummy word line DB1-0 have a faster programming speed PGMsp (e.g., marked as FAST in FIG. 2).

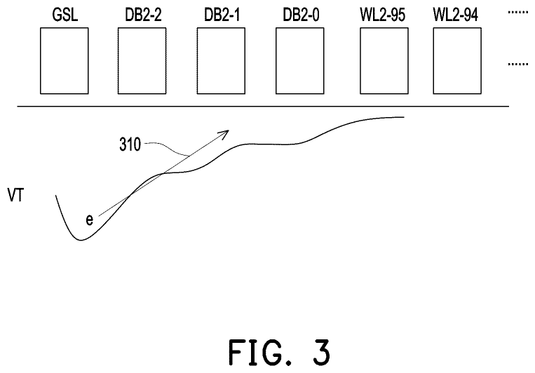

FIG. 3 is a schematic view illustrating the ideal threshold voltages VT in corresponding transistors or memory cells using the ground select lines GSL, dummy word lines DB2-0 to DB2-2 and word lines WL2-94 to WL2-95 in the memory cell string 151 as examples according to an embodiment of the present disclosure. In FIG. 3, the ground select line GSL, dummy word lines DB2-0 to DB2-2, and word lines WL2-94 to WL2-95 each has corresponding transistors or memory cells, and these transistors or memory cells each has threshold voltages VT. Ideally, to reduce the acceleration of charge e moving in the direction of arrow 310, the channel potentials of memory cells corresponding to the dummy word lines DB2-0 to DB2-2 may be set to gradual potentials to better prevent the gate induce drain leakage (GIDL). For example, the threshold voltage of the memory cells corresponding to the dummy word line DB2-0 may be designed to be greater than the threshold voltages of the memory cells corresponding to the dummy word lines DB2-1 and DB2-2, and the threshold voltage of the memory cells corresponding to the dummy word line DB2-1 may be designed to be greater than the threshold voltage of the memory cells corresponding to the dummy word line DB2-2.

An embodiment of the present disclosure may perform more precise control on the dummy word lines and corresponding dummy memory cells in the memory array. For example, based on various situations (such as the positional relationship of dummy word lines in the plurality of memory cell strings, the positional relationship between this dummy word line and other dummy word lines, and the plurality of threshold voltage states to be retained in the plurality of memory cells adjacent to the plurality of dummy word lines), the plurality of dummy word lines are divided into the plurality of dummy groups to optimize the threshold voltages of dummy memory cells in these dummy word lines. When performing dummy word line programming operations on dummy word lines, pulse signals with different programming biases may be provided for dummy word lines in different dummy groups respectively, thereby enabling each dummy memory cell to possess different threshold voltages, thus reducing hot electron acceleration effects, decreasing programming disturbance on memory cells adjacent to dummy memory cells, and allowing each memory cell to possess better data retention. Moreover, different threshold voltages VT may be set for adjacent dummy word lines respectively to reduce programming disturbance on memory cells.

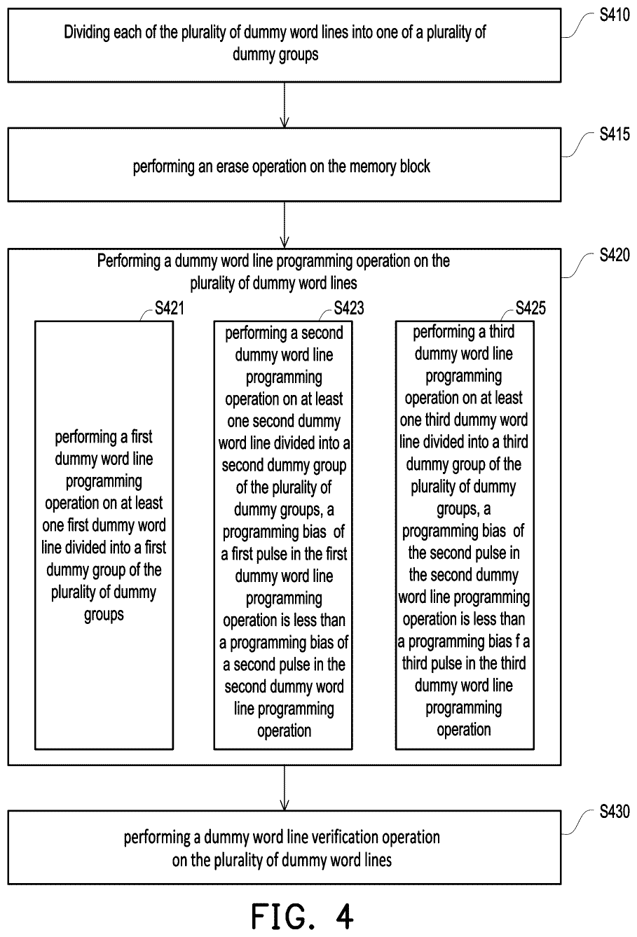

FIG. 4 is a flowchart of an operation method for a memory device according to an embodiment of the present disclosure. The operation method of FIG. 4 may be applied to the memory device 10 in FIG. 1. Please refer to FIG. 1 and FIG. 4 simultaneously. In step S410, the memory controller 110 divides each of the plurality of dummy word lines (e.g., dummy word lines DT1-0 to DT1-2, DB1-0 to DB1-1, DT2-0 to DT2-1 and DB2-0 to DB2-2) into one of the plurality of dummy groups. For example, the memory controller 110 divides each of these dummy word lines into one of the plurality of dummy groups based on the positional relationship of these dummy word lines in the memory cell string (e.g., memory cell string 151 in FIG. 1), the positional relationship between this dummy word line and other dummy word lines, and the plurality of threshold voltage states to be retained in the memory cells of this dummy word line and adjacent word lines. In this embodiment, the number of dummy groups is 3, and those applying this embodiment may adjust the number of dummy groups according to their needs. For example, these dummy word lines may be divided into 2 to 5 dummy groups. The programming bias of pulses in each dummy group may be different from each other.

In step S415, the memory controller 110 performs the erase operation on the memory block 150. In the embodiment, the erase operation of the step S415 is mainly performed on memory cells (e.g., the memory cell CM1) and corresponding word lines (e.g., the word lines WL1-0~WL1-95, WL2-0~WL2-95) of the memory block 150. And, the erase operation of the step S415 is also performed on the dummy memory cells (e.g., the dummy memory cells VDM1-0~VDM1-2, VBM1-0~VBM1-1, VDM2-0~VDM2-1, and VBM2-0~VBM2-2) and corresponding dummy word lines (e.g., the dummy word lines DT1-0~DT1-2, DB1-0~DB1-1, DT2-0~DT2-1, and DB2-0~DB2-2). In other words, the erase operation of the step S415 is performed on the word lines and the dummy word lines at the same time. The user of this embodiment may adjust the sequence of the step S410 and the step S415 according to their needs, as long as the step S410 is performed before step S420.

In the step S420, the memory controller 110 performs the dummy word line programming operation on these dummy word lines. Step S420 may include step S421 and step S423, and may also include step S425. After performing the step S420, in step S430, the memory controller 110 performs a dummy word line verification operation on these dummy word lines.

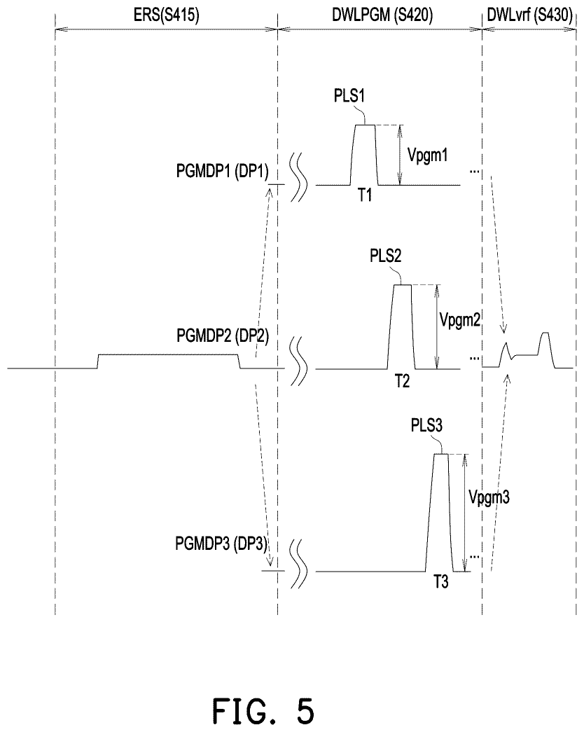

FIG. 5 is a schematic view illustrating the erase operation, the first to third dummy word line programming operations PGMDP1 to PGMDP3, and the dummy word line verification operation corresponding to the first to the third dummy groups DP1 to DP3 respectively according to the first embodiment of the present disclosure. Please refer to FIG. 4 and FIG. 5 simultaneously. In the erase phase ERS (step S415 in FIG. 4), the memory controller 110 performs the erase operation on the memory block 150. In the dummy word line programming phase DWLPGM (step S420 in FIG. 4), the memory controller 110 performs a dummy word line programming operation on these virtual word lines. In the dummy word line verification phase DWLvrf (step S430 in FIG. 4), the memory controller 110 performs the dummy word line verification operation on these dummy word lines.

In step S421, the memory controller 110 performs a first dummy word line programming operation PGMDP1 on the first dummy word line divided into the first dummy group DP1. In the dummy word line programming phase DWLPGM, a first pulse PLS1 of the first dummy word line programming operation PGMDP1 is provided to the first dummy word line divided into the first dummy group DP1 at a first time point T1, and the first pulse has a first amplitude Vpgm1.

In step S423, the memory controller 110 performs a second dummy word line programming operation PGMDP2 on the second dummy word line divided into the second dummy group DP2 In the dummy word line programming phase DWLPGM, a second pulse PLS2 of the second dummy word line programming operation PGMDP2 is provided to the second dummy word line divided into the second dummy group DP2 at a second time point T2, and the second pulse PLS2 has a second amplitude Vpgm2. The programming bias of the first pulse PLS1 (e.g., the first amplitude Vpgm1) is less than the programming bias of the second pulse PLS2 (e.g., the second amplitude Vpgm2).

In step S425, the memory controller 110 performs a third dummy word line programming operation PGMDP3 on the third dummy word line divided into the third dummy group DP3. In the dummy word line programming phase DWLPGM, a third pulse PLS3 of the third dummy word line programming operation PGMDP3 is provided to the third dummy word line divide into the third dummy group DP3 at a third time point T3, and the third pulse PLS3 has a third amplitude Vpgm3. The programming bias of the second pulse PLS2 (e.g., the second amplitude Vpgm3) is less than the programming bias of the third pulse PLS3 (e.g., the third amplitude Vpgm3). In FIG. 5, the time points T1 to T3 at which the first pulse PLS1, the second pulse PLS2, and the third pulse PLS3 are respectively provided to the dummy word lines are different from each other.

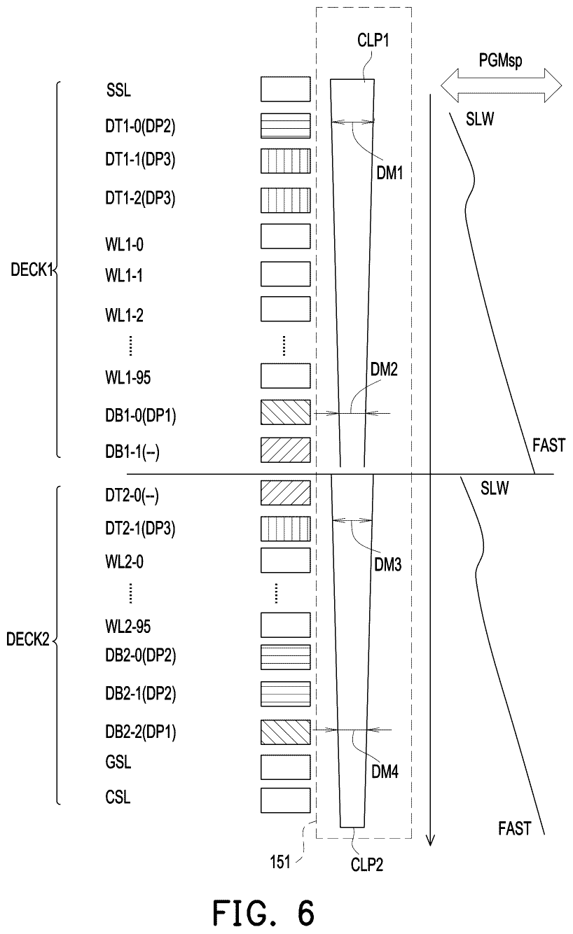

FIG. 6 is a schematic view of dummy word lines in a memory cell string 151 according to an embodiment of the present disclosure. FIG. 6 uses the dummy word lines in the memory cell string 151 as an example to illustrate how to divide the dummy word lines into one of the plurality of dummy groups. The memory cell string 151 has two channel pillars CLP1 to CLP2. Based on the positional relationships of dummy word lines DT1-0 to DT1-2 in the memory cell string 151 and the positional relationships between dummy word lines DT1-0 to DT1-2, the dummy word line DT1-0 adjacent to the string select line SSL is divided into the second dummy group DP2, and the dummy word lines DT1-1 to DT1-2 adjacent to the string select line SSL are divided into the third dummy group DP3. On the other hand, based on the positional relationships of dummy word lines DB2-0 to DB2-2 in the memory cell string 151 and the positional relationships between dummy word lines DB2-0 to DB2-2, the dummy word lines DB2-0 to DB2-1 adjacent to the ground select line GSL are divided into the second dummy group DP2, and the dummy word line DB2-2 adjacent to the ground select line GSL is divided into the first dummy group DP1, so as to conform to the ideal step potential described in FIG. 3 and better prevent charge leakage. Based on the plurality of threshold voltage states to be retained in the plurality of memory cells of the word line WL1-95 adjacent to the dummy word line DB1-0, this embodiment divides the dummy word line DB1-0 into the first dummy group DP1, reducing programming disturbance of memory cells on the word line WL1-95. Based on the plurality of threshold voltage states to be retained in the plurality of memory cells of the word line WL2-0 adjacent to the dummy word line DT2-1, this embodiment divides the dummy word line DT2-1 into the third dummy group DP3, reducing programming disturbance of memory cells on the word line WL2-0.

Dummy word lines DB1-1 and DT2-0 may have less impact on memory cells due to the absence of adjacent bit lines, therefore pulses may not be provided to dummy word lines DB1-1 and DT2-0 during the dummy word line verification phase DWLvrf of the dummy word line programming operation. In other words, dummy word lines DB1-1 and DV2-0 may not be divided into one of the first dummy group DP1 to the third dummy group DP3. Alternatively, dummy word lines DB1-1 and DV2-0 may be divided into the fourth dummy group, where this fourth dummy group does not provide pulses to the corresponding dummy word lines.

In the situation where the diameter (e.g., diameter DM2 in FIG. 6) of the dummy memory cell on the dummy word line DB1-0 corresponding to the channel pillar CLP1 is less than the diameter (e.g., diameter DM1 in FIG. 6) of the dummy memory cell on the dummy word line DT1-0, the programming bias of the pulse (e.g., first pulse PLS1) applied to the dummy memory cell on the dummy word line DB1-0 during the dummy word line programming operation is less than the programming bias of the pulse (e.g., second pulse PLS2) applied to the dummy memory cell on the dummy word line DT1-0. In the situation where the diameter (e.g., diameter DM4 in FIG. 6) of the dummy memory cell on the dummy word line DB2-2 corresponding to the channel pillar CLP2 is less than the diameter (e.g., diameter DM3 in FIG. 6) of the dummy memory cell on the dummy word line DT2-1, the programming bias of the pulse (e.g., first pulse PLS1) applied to the dummy memory cell on the dummy word line DB2-2 during the dummy word line programming operation may be less than the programming bias of the pulse (e.g., third pulse PLS3) applied to the dummy memory cell on the dummy word line DT2-1.

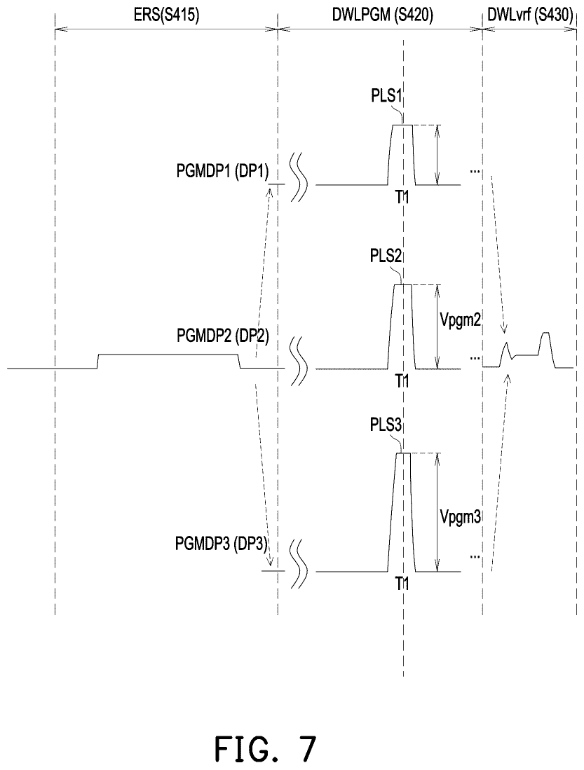

There may be the plurality of embodiments to realize the first to third dummy word line programming operations PGMDP1 to PGMDP3. FIG. 7 illustrating the erase operation, the first to third dummy word line programming operations PGMDP1 to PGMDP3, and the dummy word line verification operation corresponding to the first to the third dummy groups DP1 to DP3 respectively illustrating according to the second embodiment of the present disclosure. The difference from FIG. 5 is that in FIG. 7, the time points for providing the first pulse PLS1, the second pulse PLS2, and the third pulse PLS3 to the dummy word lines are the same, all at time points T1.

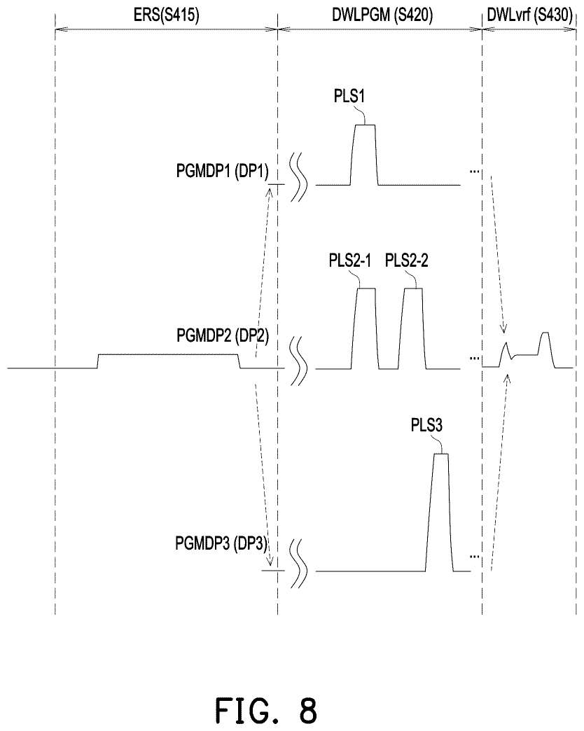

FIG. 8 is a schematic view illustrating the erase operation, the first to third dummy word line programming operations PGMDP1 to PGMDP3, and the dummy word line verification operation corresponding to the first to the third dummy groups DP1 to DP3 respectively according to the third embodiment of the present disclosure. The difference from FIG. 5 is that in FIG. 8, the second dummy word line programming operation PGMDP has two second pulses PLS2-1 and PLS2-2. The total programming bias of the second pulses PLS2-1 and PLS2-2 may be greater than the programming bias of the first pulse PLS1, and the total programming bias of the second pulses PLS2-1 and PLS2-2 may be less than the programming bias of the third pulse PLS3.

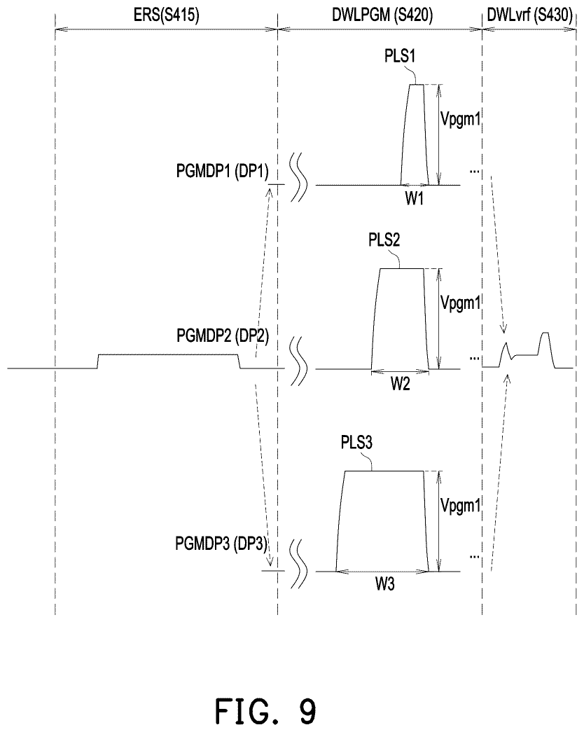

FIG. 9 is a schematic view illustrating the erase operation, the first to third dummy word line programming operations PGMDP1 to PGMDP3, and the dummy word line verification operation corresponding to the first to the third dummy groups DP1 to DP3 respectively according to the fourth embodiment of the present disclosure. The difference from FIG. 5 is that in FIG. 9, the first pulse PLS1, second pulse PLS2, and third pulse PLS3 corresponding to the first to third dummy word line programming operations PGMDP1 to PGMDP3, respectively, all have the same amplitude Vpgm1. However, the pulse width W1 of the first pulse PLS1 is greater than the pulse width W2 of the second pulse PLS2, and the pulse width W2 of the second pulse PLS2 is greater than the pulse width W3 of the third pulse PLS3. Therefore, the programming bias of the first pulse PLS1 is greater than the programming bias of the second pulse PLS2, and the programming bias of the second pulse PLS2 is greater than the programming bias of the third pulse PLS3.

In summary, the embodiments of the present disclosure may divide the plurality of dummy word lines into the plurality of dummy groups based on many situations (e.g., the positional relationship of this dummy word line in the plurality of memory cell strings, the positional relationship between this dummy word line and other dummy word lines, the plurality of threshold voltage states to be retained in the plurality of memory cells adjacent to the plurality of dummy word lines). When performing the dummy word line programming operation on the dummy word lines, pulse signals with different programming bias are provided for dummy word lines in different dummy groups, thereby reducing the programming disturbance on memory cells, thus allowing each memory cell to possess better data retention.

What is claimed is:

1. An operation method of a memory device, the memory device comprising a memory block, the memory block comprising at least one memory cell string, wherein the at least one memory cell string comprises a string select transistor, a plurality of memory cells, and a ground select transistor sequentially connected in series, the at least one memory cell string further comprising a plurality of dummy memory cells between the string select transistor and the plurality of memory cells, the plurality of memory cells, and the plurality of memory cells and the ground select transistor, wherein the plurality of memory cells are respectively coupled to a plurality of word lines, the plurality of dummy memory cells are respectively coupled to a plurality of dummy word lines,
the operation method comprising:
dividing each of the plurality of dummy word lines into one of a plurality of dummy groups;
performing an erase operation on the plurality of dummy word lines;
performing a dummy word line programming operation on the plurality of dummy word lines; and
performing a dummy word line verification operation on the plurality of dummy word lines,
wherein the dummy word line programming operation comprises:
performing a first dummy word line programming operation on at least one first dummy word line divided into a first dummy group of the plurality of dummy groups; and
performing a second dummy word line programming operation on at least one second dummy word line divided into a second dummy group of the plurality of dummy groups,
wherein a programming bias of a first pulse in the first dummy word line programming operation is less than a programming bias of a second pulse in the second dummy word line programming operation.

2. The operation method as claimed in claim 1, further comprising:
dividing the each of the plurality of dummy word lines into the one of the plurality of dummy groups based on a positional relationship of the plurality of dummy word lines in the at least one memory cell string, a positional relationship among the plurality of dummy word lines, and a plurality of threshold voltage states to be retained in the plurality of memory cells of the plurality of word lines adjacent to the plurality of dummy word lines.

3. The operation method as claimed in claim 1, wherein the plurality of dummy groups further comprises a third dummy group,
wherein, the dummy word line programming operation further comprises:
performing a third dummy word line programming operation on at least one third dummy word line divided into the third dummy group, wherein the programming bias of the second pulse in the second dummy word line programming operation is less than a programming bias of a third pulse in the third dummy word line programming operation.

4. The operation method as claimed in claim 3, wherein time points for providing the first pulse, the second pulse, and the third pulse to the plurality of dummy word lines respectively are different from each other.

5. The operation method as claimed in claim 3, wherein the string select transistor is coupled to a string select line, and one of the plurality of dummy word lines adjacent to the string select line is divided into the second dummy group or the third dummy group.

6. The operation method as claimed in claim 3, wherein the ground select transistor is coupled to a ground select line, and one of the plurality of dummy word lines adjacent to the ground select line is divided into the first dummy group or the second dummy group.

7. The operation method as claimed in claim 1, wherein the memory block is formed by stacking one or more memory stack layers, each of the at least one memory cell string comprises one or more channel pillars, wherein the one or more channel pillars correspond to the one or more memory stack layers respectively, and the plurality of dummy memory cells are disposed at boundary positions of the one or more channel pillars.

8. The operation method as claimed in claim 7, wherein the plurality of dummy memory cells and the plurality of dummy word lines form a plurality of dummy layers, and the plurality of dummy layers are located at boundary positions on both sides of the one or more memory stack layers.

9. The operation method as claimed in claim 7, wherein, in a situation where a first diameter corresponding to a first dummy memory cell in the one or more channel pillars is less than a second diameter corresponding to a second dummy memory cell in the one or more channel pillars, an programming bias of a pulse applied to the first dummy memory cell in the dummy word line programming operation is less than an programming bias of a pulse applied to the second dummy memory cell.

10. A memory device, comprising:
a memory array, comprising at least one memory cell string, wherein the at least one memory cell string comprises a string select transistor, a plurality of memory cells, and a ground select transistor connected sequentially connected in series, the at least one memory cell string further comprises a plurality of dummy memory cells between the string select transistor and the plurality of memory cells, the plurality of memory cells, and the plurality of memory cells and the ground select transistor, wherein the plurality of memory cells are respectively coupled to a plurality of word lines, the plurality of dummy memory cells are respectively coupled to a plurality of dummy word lines; and
a memory controller, for controlling the memory array,
wherein the memory controller is configured to:
divide each of the plurality of dummy word lines into one of a plurality of dummy groups;
perform an erase operation on the plurality of dummy word lines;
perform a dummy word line programming operation on the plurality of dummy word lines; and
performing a dummy word line verification operation on the plurality of dummy word lines,
wherein the dummy word line programming operation comprises:
performing a first dummy word line programming operation on at least one first dummy word line divided into a first dummy group of the plurality of dummy groups; and
performing a second dummy word line programming operation on at least one second dummy word line divided into a second dummy group of the plurality of dummy groups,
wherein a programming bias of a first pulse in the first dummy word line programming operation is less than a programming bias of a second pulse in the second dummy word line programming operation.

11. The memory device as claimed in claim 10, wherein the memory controller is further configured to:
divide the each of the plurality of dummy word lines into the one of the plurality of dummy groups based on a positional relationship of the plurality of dummy word lines in the at least one memory cell string, a positional relationship among the plurality of dummy word lines, and a plurality of threshold voltage states to be retained in the plurality of memory cells of the plurality of word lines adjacent to the plurality of dummy word lines.

12. The memory device as claimed in claim 10, wherein the plurality of dummy groups further comprises a third dummy group,
wherein, the memory controller is further configured to:
perform a third dummy word line programming operation on at least one third dummy word line divided into the third dummy group, wherein the programming bias of the second pulse in the second dummy word line programming operation is less than a programming bias of a third pulse in the third dummy word line programming operation.

13. The memory device as claimed in claim 12, wherein, time points for providing the first pulse, the second pulse, and the third pulse to the plurality of dummy word lines respectively are different from each other.

14. The memory device as claimed in claim 12, wherein the string select transistor is coupled to a string select line, and one of the plurality of dummy word lines adjacent to the string select line is divided into the second dummy group or the third dummy group.

15. The memory device as claimed in claim 12, wherein the ground select transistor is coupled to a ground select line, and one of the plurality of dummy word lines adjacent to the ground select line is divided into the first dummy group or the second dummy group.

16. The memory device as claimed in claim 10, wherein the memory array is formed by stacking one or more memory stack layers, each of the at least one memory cell string comprises one or more channel pillars, wherein the one or more channel pillars correspond to the one or more memory stack layers respectively, and the plurality of dummy memory cells are disposed at boundary positions of the one or more channel pillars.

17. The memory device as claimed in claim 16, wherein the plurality of dummy memory cells and the plurality of dummy word lines form a plurality of dummy layers, and the plurality of dummy layers are disposed at boundary positions on both sides of the one or more memory stack layers.

18. The memory device as claimed in claim 16, wherein, in a situation where a first diameter corresponding to a first dummy memory cell in the one or more channel pillars is less than a second diameter corresponding to a second dummy memory cell in the one or more channel pillars, a programming bias of a pulse applied to the first dummy memory cell in the dummy word line programming operation is less than a programming bias of a pulse applied to the second dummy memory cell.
